(19) United States
(12) Patent Application Publication
(10) Pub. No.: US 2026/0059732 A1
(43) Pub. Date: Feb. 26, 2026

(54) SEMICONDUCTOR DEVICE AND METHOD FOR OPERATING THE SAME

(71) Applicant: SK hynix Inc., Gyeonggi-do (KR)

(72) Inventors: Jung Woo PARK, Gyeonggi-do (KR); Dong Soo KIM, Gyeonggi-do (KR)

(21) Appl. No.: 19/069,240

(22) Filed: Mar. 4, 2025

(30) Foreign Application Priority Data
Aug. 23, 2024 (KR) 10-2024-0113384

(51) Int. Cl. H10B 12/00; G11C 11/405; G11C 11/406

(52) U.S. Cl. CPC H10B 12/00; G11C 11/405; G11C 11/406

(57) ABSTRACT

A semiconductor device including one or more memory cells and a method for operating the same are disclosed. Each of the memory cells includes a first transistor configured to write data, a second transistor configured to store the data, and a third transistor configured to refresh the data. The memory cell includes a first transistor including a first gate connected to a write word line and one terminal connected to a storage node, a second transistor including a second gate connected to the storage node and one terminal connected to a read word line and a third transistor including a third gate connected to the read word line and one terminal connected to a read bit line.

### CROSS-REFERENCE TO RELATED APPLICATION

This patent application claims the priority and benefits of Korean patent application No. 10-2024-0113384, filed on Aug. 23, 2024, the disclosure of which is incorporated herein by reference in its entirety.

### TECHNICAL FIELD

Embodiments of the present disclosure generally relate to a semiconductor device and a method for operating the same, and more particularly to a semiconductor device including memory cells and a method for operating the same.

### BACKGROUND

A semiconductor device having a memory function among various semiconductor devices may include, as a device that can be used to store information, an array including individual memory cells including transistors. The semiconductor device having a memory function may include, for example, a dynamic random access memory (DRAM). A memory semiconductor may include bit lines and word lines that may cross each other in a vertical direction. The bit lines and word lines may extend across an array including the memory cells. The bit lines and word lines can be used to access individual memory cells.

Memory performance, cell stability and reliability, power efficiency, ease of processing, cost, etc. can vary depending on how individual memory cells are designed and placed, and thus research on a cell array design of a memory device and a fabrication process of the cell array is being actively conducted.

### SUMMARY

Various embodiments of the present disclosure relate to a semiconductor device capable of replacing a capacitor designed to store data in a unit memory cell with a transistor.

Various embodiments of the present disclosure relate to a semiconductor device including a structure in which a plurality of transistors included in a unit memory cell can be stacked.

In accordance with an embodiment of the present disclosure, a memory cell may include a first gate configured to contact a write word line; a second gate disposed below the first gate and disposed over a read bit line, and configured to penetrate a read word line; a third gate spaced apart from the second gate and disposed over the read bit line; a first interconnect structure configured to have a portion contacting the second gate and another portion penetrated by the third gate; and a second interconnect structure configured to contact each read word line and the third gate.

In some embodiments, the first gate may be configured to penetrate the write bit line; the write word line and the read word line may be configured to extend in a first direction; and the write bit line and the read bit line may be configured to extend in a second direction different from the first direction.

In some embodiments, the first interconnect structure may include a first horizontal interconnect layer configured to contact the second gate; a second horizontal interconnect layer configured to be penetrated by the third gate; and a vertical interconnect layer configured to contact each of the first horizontal interconnect layer and the second horizontal interconnect layer.

In some embodiments, a first channel layer formed to contact a side surface and a bottom surface of the first gate may be configured to contact the write bit line; a second channel layer formed to contact a side surface and a bottom surface of the second gate may be configured to contact the read word line; and a third channel layer formed to contact a side surface and a bottom surface of the third gate may be configured to contact the second horizontal interconnect layer.

In some embodiments, each of the first to third channel layers may be configured to include an oxide semiconductor.

In some embodiments, the oxide semiconductor may be configured to include at least one of In—Sn—Ga—Zn—O, In—Ga—Zn—O, In—Al—Zn—O, Sn—Ga—Zn—O, Al—Ga—Zn—O, Sn—Al—Zn—O, In—Zn—O, Sn—Zn—O, Al—Zn—O, Zn—Mg—O, Sn—Mg—O, In—Mg—O, and In—Ga—O.

In some embodiments, each of the first to third gates may extend in a third direction perpendicular to the first direction, wherein the second gate is arranged spaced apart from the first gate in the third direction, and a height of the second gate in the third direction is higher than a height of the third gate in the third direction.

In accordance with another embodiment of the present disclosure, a semiconductor device may include a first transistor including a first gate connected to a write word line and having one terminal connected to a storage node; a second transistor including a second gate connected to the storage node and having one terminal connected to a read word line; and a third transistor including a third gate connected to the read word line and having one terminal connected to a read bit line.

In some embodiments, the second transistor may include another terminal connected to the read bit line; and the third transistor may include another terminal connected to the storage node.

In some embodiments, the first transistor may include another terminal connected to a write bit line.

In some embodiments, when a first word line signal is applied to the write word line and the first word line signal has a high level, the first transistor may be turned on; and when the first word line signal has a low level, the first transistor may be turned off.

In some embodiments, when the first word line signal has a high level and a first bit line signal applied to the write bit line has a high level, data “1” may be stored in the storage node; and when the first word line signal has a high level and the first bit line signal has a low level, data “0” may be stored in the storage node.

In some embodiments, when the data “1” is stored in the storage node, the second transistor may be turned on; and when the data “0”is stored in the storage node, the second transistor may be turned off.

In some embodiments, when a second word line signal is applied to the read word line and the second transistor is turned on, a second bit line signal having a high level may be applied to the read bit line; and when a second word line signal is applied to the read word line and the second transistor is turned off, a second bit line signal having a low level may be applied to the read bit line.

In some embodiments, the read word line may be configured to receive a second word line signal for turning on the third transistor; and the third transistor may be configured to refresh data stored in the storage node.

In accordance with another embodiment of the present disclosure, a method for operating a semiconductor device may include applying a first word line signal to a gate of a first transistor; storing data corresponding to a level of a first bit line signal applied to one terminal of the first transistor in a storage node connected to the second transistor; applying a second word line signal to one terminal of the second transistor; outputting a second bit line signal corresponding to the data to another terminal of the second transistor; applying the second bit line signal to one terminal of a third transistor; and refreshing the data stored in the storage node.

In some embodiments, when the first word line signal has a high level, the first transistor may be turned on; and when the first word line signal has a low level, the first transistor may be turned off.

In some embodiments, when the first bit line signal has a high level, the data may be “1”; and when the first bit line signal has a low level, the data may be “0”.

In some embodiments, when the data is “1”, the second transistor may be turned on; and when the data is “0”, the second transistor may be turned off.

In some embodiments, when the data is “1”, the second bit line signal may have a high level; and when the data is “0”, the second bit line signal may have a low level.

In some embodiments, when the second bit line signal is at the high level, the data stored in the storage node may be refreshed to “1”; and when the second bit line signal is at the low level, the data stored in the storage node may be refreshed to “0”.

It is to be understood that both the foregoing general description and the following detailed description of the embodiments of the present disclosure are illustrative and are intended to provide further description of the invention as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a circuit diagram illustrating a portion of a semiconductor device based on some embodiments of the present disclosure.

FIGS. 2A and 2B are timing diagrams illustrating an operation of writing and reading data “1” into and from a memory cell shown in FIG. 1 based on some embodiments of the present disclosure.

FIGS. 3A and 3B are timing diagrams illustrating an operation of writing and reading data “0” into and from the memory cell shown in FIG. 1 based on some embodiments of the present disclosure.

FIG. 4 is a flowchart illustrating an operation of refreshing data of the memory cell shown in FIG. 1 based on some embodiments of the present disclosure.

FIG. 5 is a plan view illustrating a portion of a memory cell array in which the memory cell of FIG. 1 is used as a unit memory cell based on some embodiments of the present disclosure.

FIG. 6 is a cross-sectional view illustrating the memory cell array taken along the line A-A′ of FIG. 5 based on some embodiments of the present disclosure.

FIG. 7 is a three-dimensional (3D) view illustrating memory cells shown in FIG. 5 based on some embodiments of the present disclosure.

FIG. 8 is a three-dimensional view illustrating an arrangement of the plurality of memory cells show in FIG. 5 based on some embodiments of the present disclosure.

### DETAILED DESCRIPTION

The present disclosure provides embodiments and examples of a semiconductor device and a method for operating the same that may be used in configurations to substantially address one or more technical or engineering issues and to mitigate limitations or disadvantages encountered in some semiconductor devices in the art. Some embodiments of the present disclosure relate to a semiconductor device including memory cells and a method for operating the same. Some embodiments of the present disclosure relate to a semiconductor device capable of replacing a capacitor designed to store data in a unit memory cell with a transistor. Some embodiments of the present disclosure relate to a semiconductor device including a structure in which a plurality of transistors included in a unit memory cell can be stacked.

Reference will now be made in detail to the embodiments of the present disclosure, examples of which are illustrated in the accompanying drawings. Wherever possible, the same reference numbers will be used throughout the drawings to refer to the same or like parts. While this disclosure is susceptible to various modifications and alternative forms, specific embodiments thereof are shown by way of example in the drawings. However, the present disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of advantageous effects capable of being directly or indirectly recognized.

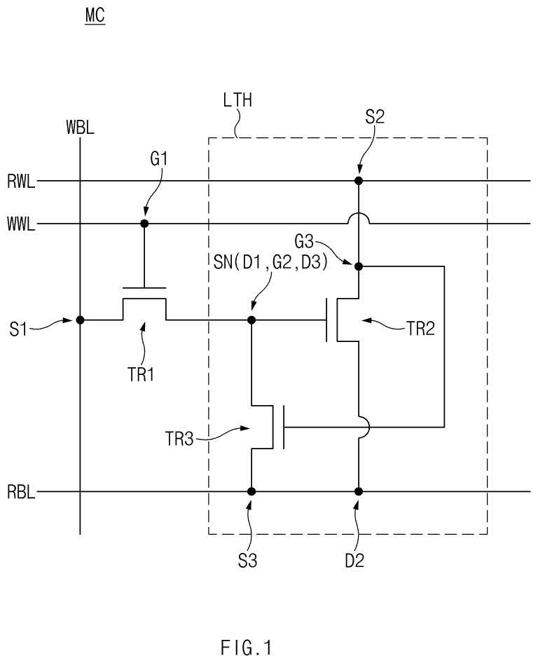

FIG. 1 is a circuit diagram illustrating a portion of a semiconductor device based on some embodiments of the present disclosure.

Referring to FIG. 1, the semiconductor device may be a memory device capable of storing data therein. The memory device may refer to a device that temporarily or permanently stores data in an electronic device such as a computer, a smartphone, etc. The memory device may be classified into a non-volatile memory and a volatile memory. The non-volatile memory may be a memory device that continues to maintain stored information even when power is not supplied thereto. Examples of the non-volatile memory may include a read only memory (ROM), a flash memory, a hard disk drive (HDD), etc. The volatile memory may be a memory device that requires power supply to preserve stored information. Examples of the volatile memory include dynamic random access memory (DRAM), static random access memory (SRAM), etc. In some embodiments, the DRAM will hereinafter be described as an example of a semiconductor device for convenience of description.

The semiconductor device may include a memory cell (MC), a write word line (WWL), a write bit line (WBL), a read word line (RWL), and a read bit line (RBL).

The memory cell (MC) may include a first transistor (TR1) and a latch (LTH). The memory cell (MC) may be a unit cell constituting a memory cell array included in the semiconductor device. The memory cell (MC) may be a minimum unit that stores data within the semiconductor device.

The first transistor (TR1) may operate as a write transistor. The first transistor (TR1) may include a first gate terminal (G1), a first source terminal (S1), and a first drain terminal (D1). The first gate terminal (G1) may be connected to a write word line (WWL). The first source terminal (S1) may be connected to a write bit line (WBL). The first drain terminal (D1) may be connected to a storage node (SN). When the first transistor (TR1) is turned on, a first channel through which charge carriers can move is formed, so that the first source terminal (S1) and the first drain terminal (D1) can be electrically connected to each other. When the first transistor (TR1) is turned off, the first channel may not be formed.

The write word line (WWL) may transmit the first word line signal to the first gate terminal (G1) of the first transistor (TR1), so that the write word line (WWL) can control the on/off operations of the first transistor (TR1) and can control the data write operation. When the first word line signal has a high level, the first transistor (TR1) may be turned on. The high level of the first word line signal may mean, for example, a voltage level higher than a threshold voltage of the first transistor (TR1). When the first word line signal has a low level, the first transistor (TR1) may be turned off. The above low level of the first word line signal may mean, for example, a voltage level lower than the threshold voltage of the first transistor (TR1).

The write bit line (WBL) may determine data to be written into the memory cell (MC). The write bit line (WBL) may receive a first bit line signal. When the first bit line signal has a high level, a logic to be written into the memory cell (MC) may be a logic value “1”. The high level of the first bit line signal may mean, for example, a voltage level higher than the threshold voltage of the second transistor (TR2). When the first bit line signal has a low level, a logic to be written into the memory cell (MC) may be a logic value “0”. The low level of the first bit line signal may mean, for example, a voltage level lower than the threshold voltage of the second transistor (TR2).

When the first word line signal has a high level and the first bit line signal has a high level or a low level, the data write operation may be performed.

In the memory cell (MC) where the data write operation is performed, when the first word line signal has a high level and the first bit line signal has a high level, the first transistor (TR1) may be turned on, and data “1” may be stored in the storage node (SN). When the first word line signal has a high level and the first bit line signal has a low level, the first transistor (TR1) may be turned on, and data “0” may be stored in the storage node (SN).

When the first word line signal has a low level, the first transistor (TR1) may be turned off, and the data write operation may not be performed.

The latch (LTH) may include a second transistor (TR2), a third transistor (TR3), and a storage node (SN).

The storage node (SN) may be connected to a first drain terminal (D1), a second gate terminal (G2), and a third drain terminal (D3). The storage node (SN) may store data therein. When data “1” is stored in the storage node (SN), the voltage level of the storage node (SN) may have a high level, for example, a voltage level higher than the threshold voltage of the second transistor (TR2).

The voltage level of the storage node (SN) where data “1” is stored may be the same as the high level of the first word line signal, but may vary due to variables such as leakage over time. When data “0” is stored in the storage node (SN), the voltage level of the storage node (SN) may have a low level, for example, a voltage level lower than the threshold voltage of the second transistor (TR2).

The second transistor (TR2) may operate as a read transistor. The second transistor (TR2) may include a second gate terminal (G2), a second source terminal (S2), and a second drain terminal (D2). The second gate terminal (G2) may be connected to the storage node (SN). The second source terminal (S2) may be connected to a read word line (RWL). The second drain terminal (D2) may be connected to a read bit line (RBL). When data “1” is stored in the storage node (SN), the second transistor (TR2) may be turned on. When logic “0” is stored in the storage node (SN), the second transistor (TR2) may be turned off. When the second transistor (TR2) is turned on, a second channel through which charge carriers can move is formed, so that the second source terminal (S2) and the second drain terminal (D2) can be electrically connected to each other. When the second transistor (TR2) is turned off, the second channel may not be formed.

The read word line (RWL) may control the data read operation by transmitting a second word line signal to the second source terminal (S2) of the second transistor (TR2). The second word line signal may have a high level or a low level. When the second word line signal has a high level, the data read operation may be performed. When the second word line signal has a low level, the data read operation may not be performed. The high level of the second word line signal may be, for example, the same voltage level as the high level of the first bit line signal. The low level of the second word line signal may be, for example, the same voltage level as the low level of the first bit line signal.

The read word line (RWL) may control the on/off operations of the third transistor (TR3) by transmitting the second word line signal to the third gate terminal (G3) of the third transistor (TR3), and may control the data refresh operation.

The read bit line (RBL) may be a line that outputs data stored in the storage node (SN). The read bit line (RBL) may be a line that outputs the second bit line signal in a data read operation. The second bit line signal may vary depending on whether the data stored in the storage node (SN) is “1” or “0”. The second bit line signal may have a high level or a low level. The second bit line signal may have a low level while the data read operation is not performed. The low level of the second bit line signal may be, for example, the same voltage level as the low level of the second word line signal. The high level of the second bit line signal may be the same voltage level as the high level of the second word line signal. In the data read operation, when the second word line signal has a high level and data “1” is stored in the storage node (SN), the second transistor (TR2) may be turned on, and a second bit line signal of a high level may be output from the read bit line (RBL). In the data read operation, when the second word line signal has a high level and data “0” is stored in the storage node (SN), the second transistor (TR2) may be turned off, and a second bit line signal of a low level may be output from the read bit line (RBL).

The third transistor (TR3) may operate as a refresh transistor. The third transistor (TR3) may include a third gate terminal (G3), a third source terminal (S3), and a third drain terminal (D3). The third gate terminal (G3) may be connected to the read word line (RWL). The third source terminal (S3) may be connected to the read bit line (RBL). The third drain terminal (D3) may be connected to the storage node (SN). When the second word line signal has a high level, the third transistor (TR3) may be turned on. When the third transistor (TR3) is turned on, a third channel through which charge carriers may move is formed, so that the third source terminal (S3) and the third drain terminal (D3) may be electrically connected to each other. When the third transistor (TR3) is turned off, the third channel may not be formed.

When the data stored in the storage node (SN) is “1”, the second transistor (TR2) is turned on, so that, when the second word line signal applied to the second source terminal (S2) has a high level, the second bit line signal applied to the second drain terminal (D2) may also have a high level. When the second word line signal applied to the third gate terminal (G3) has a high level, the third transistor (TR3) is turned on, so that the voltage level of the storage node (SN) connected to the third drain terminal (D3) can be refreshed to a high level by the second bit line signal that is transmitted to the third source terminal (S3) and has a high level.

When the data stored in the storage node (SN) is “0”, the second transistor (TR2) is turned off, and when the second word line signal applied to the third gate terminal (G3) has a high level, the third transistor (TR3) is turned on, so that the voltage level of the storage node (SN) connected to the third drain terminal (D3) can be refreshed to a low level by the second bit line signal that is transmitted to the third source terminal (S3) and has a low level.

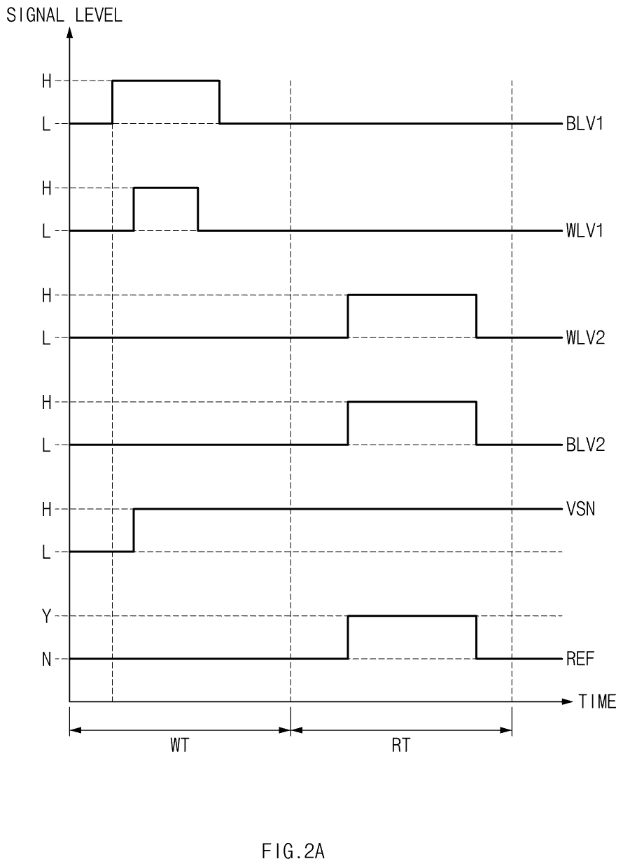

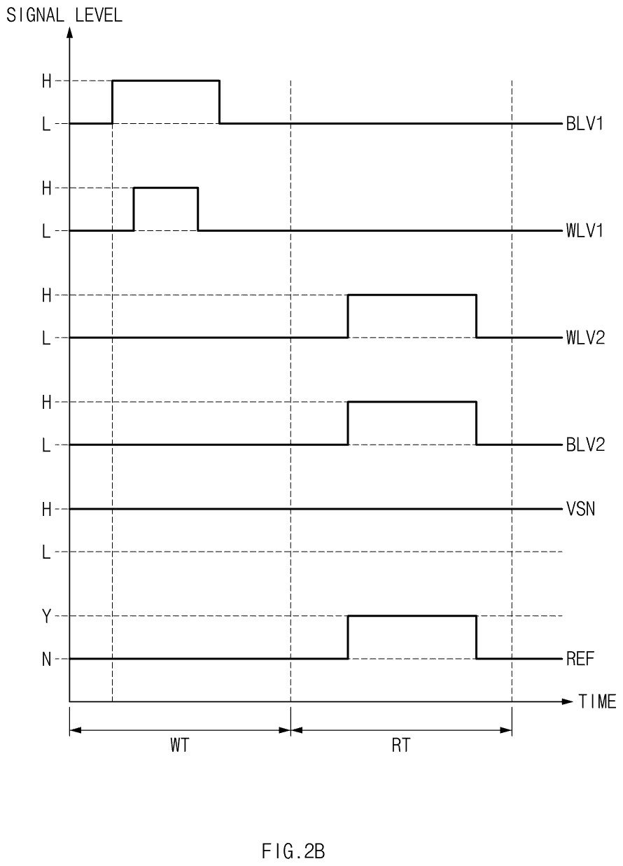

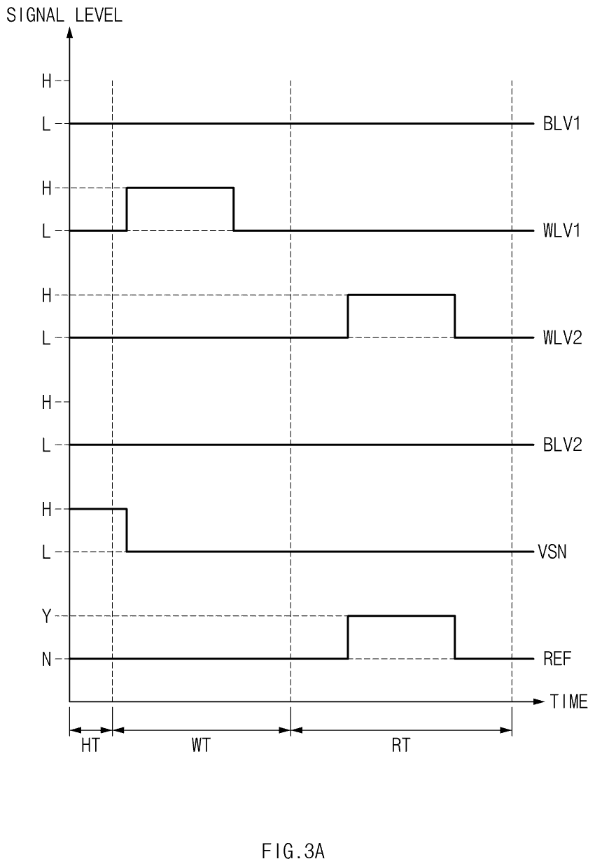

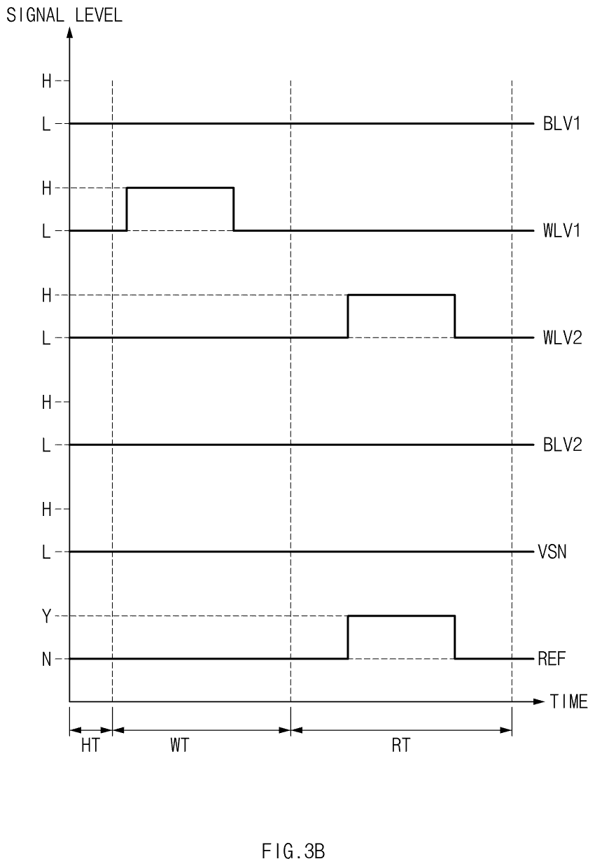

Among the signal levels indicated by the vertical axes of FIGS. 2A, 2B, 3A, and 3B below, “H” may denote a high level, “L” may denote a low level, “Y” may denote a state in which a refresh operation (REF) is in progress (i.e., a refresh signal REF is activated at a high level), and “N” may denote a state in which the refresh operation (REF) is not in progress (i.e., the refresh signal REF is deactivated at a low level).

FIGS. 2A and 2B are timing diagrams illustrating an operation of writing and reading data “1” into and from the memory cell (MC) shown in FIG. 1 based on some embodiments of the present disclosure.

When a state in which neither the data write operation nor the data read operation is performed in the memory cell (MC) is referred to as a hold state, the diagram of FIG. 2A illustrates the operation of writing and reading data “1” into and from the memory cell (MC) while the storage node voltage (VSN) is at a low level in the hold state. The timing diagram of FIG. 2B may be a timing diagram showing the operation of writing and reading data “1” into and from the memory cell (MC) while a storage node voltage (VSN) is at a high level in the hold state.

Referring to FIGS. 1 and 2A, in a hold period (HT) in which the memory cell (MC) is in the hold state, a first bit line signal (BLV1) applied to the first source terminal (S1) by the write bit line (WBL), a first word line signal (WLV1) applied to the first gate terminal (G1) by the write word line (WWL), a second word line signal (WLV2) applied to each of the second source terminal (S2) and the third gate terminal (G3) by the read word line (RWL), and a second bit line signal (BLV2) applied to the third source terminal (S3) by the read bit line (RBL) may all be at a low level. In the hold period (HT), the refresh operation of the storage node (SN) may not occur (REF_N), and the storage node voltage (VSN) may be at a low level.

The operation of writing data “1” into the storage node (SN) in the memory cell (MC) may be configured such that, in a data write period (WT), a first bit line signal (BLV1) having a low level may become a high level. After the first bit line signal (BLV1) becomes a high level, a first word line signal (WLV1) having a low level may also become a high level.

When the first word line signal (WLV1) becomes a high level, the first transistor (TR1) is turned on, and data “1” may be stored in the storage node (SN) by the first bit line signal (BLV1) having a high level. The state in which data “1” is stored in the storage node (SN) may be a state in which the storage node voltage (VSN) has a high level.

Afterwards, when the first word line signal (WLV1) becomes a low level, the first transistor (TR1) is turned off, and while the storage node voltage (VSN) is maintained at a high level, the storage node (SN) and the write bit line (WBL) can be electrically separated from each other. When the first bit line signal (BLV1) also becomes a low level, the data write period (WT) can be terminated.

In the operation of reading data “1” of the storage node (SN) from the memory cell (MC), the second word line signal (WLV2) having a low level may become a high level in the data read period (RT). Since the storage node voltage (VSN) is at a high level, the second transistor (TR2) may be turned on. In a situation where the second transistor (TR2) is turned on, when the second word line signal (WLV2) becomes a high level, the second bit line signal (BLV2) having a low level may also become a high level. When the second bit line signal (BLV2) transitions to a high level, data “1”can be output by the read bit line (RBL).

In addition, when the second word line signal (WLV2) transitions to a high level, the third transistor (TR3) is turned on, and the refresh operation of the storage node (SN) may be performed (REF). As the second bit line signal (BLV2) transitions to a high level, the storage node voltage (VSN) can be refreshed to maintain the high level.

Referring to FIGS. 2A and 2B, even in the timing diagram of FIG. 2B that shows a timing diagram in which data “1” is rewritten into the memory cell (MC) including the storage node (SN) in which data “1” has already been stored, the data write operation and the data read operation can also be performed in the same manner as described in FIG. 2A.

FIGS. 3A and 3B are timing diagrams illustrating the operation of writing and reading data “0” into and from the memory cell shown in FIG. 1 based on some embodiments of the present disclosure.

The timing diagram of FIG. 3A may be a timing diagram illustrating the operation of writing and reading “0” into and from the memory cell (MC) in a state in which the storage node voltage (VSN) is at a high level in a hold state. The timing diagram of FIG. 3B may be a timing diagram illustrating the operation of writing and reading data “0” in a state in which the storage node voltage (VSN) is at a low level in a hold state.

Referring to FIGS. 1 and 3A, in the hold period (HT) in which the memory cell (MC) is in a hold state, each of a first bit line signal (BLV1), a first word line signal (WLV1), a second word line signal (WLV2), and a second bit line signal (BLV2) may all be at a low level. In the hold period (HT), the refresh operation of the storage node (SN) may not occur (REF_N), and the storage node voltage (VSN) may be at a high level (i.e., a state in which data “1”is stored).

The operation of writing data “0” into the storage node (SN) may be configured such that, in the data write period (WT), the first bit line signal (BLV1) having a low level can be maintained at a low level. In addition, the first word line signal (WLV1) having a low level may be at a high level.

When the first word line signal (WLV1) transitions to a high level, the first transistor (TR1) is turned on, and data “0” can be stored in the storage node (SN) by the first bit line signal (BLV1) having a low level. The state in which data “0” is stored in the storage node (SN) may be a state in which the storage node voltage (VSN) has a low level.

Thereafter, when the first word line signal (WLV1) transitions to a low level, the first transistor (TR1) is turned off, and while the storage node voltage (VSN) is also maintained at a low level, the storage node (SN) and the write bit line (WBL) can be electrically separated from each other. When the first bit line signal (BLV1) also transitions to a low level, the data write period (WT) can be terminated.

The operation of reading data “0” from the storage node (SN) in the memory cell (MC) may be configured such that, in the data read period (RT), the second word line signal (WLV2) having a low level may transition to a high level. Since the storage node voltage (VSN) is at a low level, the second transistor (TR2) may remain turned off. Since the second transistor (TR2) remains turned off, the second bit line signal (BLV2) can be maintained at a low level even though the second word line signal (WLV2) has a high level. As the second bit line signal (BLV2) maintains a low level, data “0”can be output by the read bit line (RBL).

When the second word line signal (WLV2) transitions to a high level, the third transistor (TR3) may be turned on, and the refresh operation of the storage node (SN) may be performed (REF). As the second bit line signal (BLV2) maintains a low level, the storage node voltage (VSN) may also be refreshed to maintain a low level.

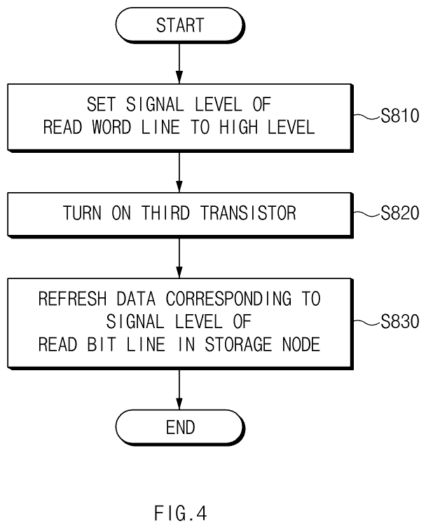

FIG. 4 is a flowchart illustrating an operation of refreshing data of the memory cell shown in FIG. 1 based on some embodiments of the present disclosure.

Referring to FIGS. 1 and 4, data of the memory cell (MC), particularly a memory cell (MC) in which data “1” is written, may require a refresh operation because a leakage phenomenon in which the storage node voltage (VSN of FIGS. 2A and 2B) gradually decreases over time may occur. For the refresh operation, the voltage (signal level) of the read word line (RWL) may have a high level (S810). Since the storage node voltage (VSN) has already been in a high level state in the case of a storage node (SN) in which data “1” is written, the second transistor (TR2) may be turned on.

As the voltage of the read word line (RWL) has a high level, the third transistor (TR3) may also be turned on (S820). As the second transistor (TR2) is turned on, the read bit line (RBL) electrically connected to the second drain terminal (D2) may also have a high level.

As the voltage of the read bit line (RBL) has a high level, the voltage of the storage node (SN) is refreshed to a high level by the turned-on third transistor (TR3), and as a result, data stored in the memory cell (MC) can be refreshed (S830).

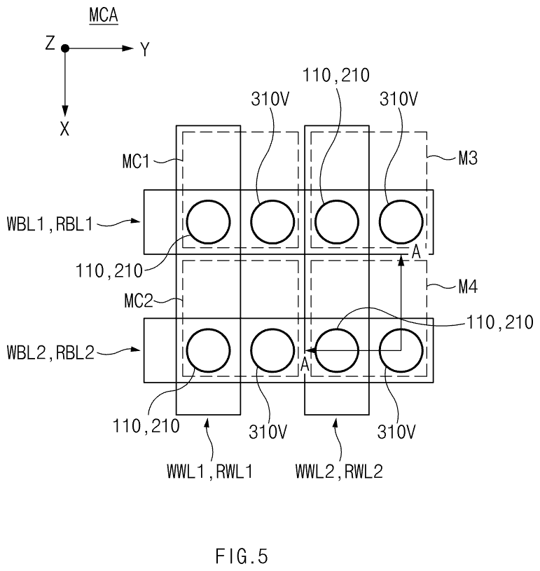

FIG. 5 is a plan view illustrating a portion of a memory cell array (MCA) in which the memory cell (MC) of FIG. 1 is used as a unit memory cell based on some embodiments of the present disclosure.

Referring to FIG. 1 and FIG. 5, a memory cell array (MCA) in which the memory cell (MC) of FIG. 1 is used as a unit memory cell may be a configuration for storing data within a semiconductor device. When modeling the memory cell array (MCA) as a circuit diagram, the circuit diagram of FIG. 1 may be modeled to be repeatedly arranged. In FIG. 5, a memory cell array (MCA) in which four memory cells (MC1˜MC4) are arranged in a (2×2) matrix structure is illustrated, but the number of memory cells is not limited thereto. For example, a plurality of memory cells may be further arranged in a first direction (X), a second direction (Y), or a third direction (Z). The memory cell array (MCA) may include first to fourth memory cells (MC1˜MC4).

A first memory cell (MC1) may overlap a first write bit line (WBL1), a first read bit line (RBL1), a first write word line (WWL1), and a first read bit line (RWL1). A second memory cell (MC2) may overlap a second write bit line (WBL2), a second read bit line (RBL2), a first write word line (WWL1), and a first read bit line (RWL1). A third memory cell (MC3) may overlap a first write bit line (WBL1), a first read bit line (RBL1), a second write word line (WWL2), and a second read bit line (RWL2). A fourth memory cell (MC4) may overlap a second write bit line (WBL2), a second read bit line (RBL2), a second write word line (WWL2), and a second read bit line (RWB2). Each of the first to fourth memory cells (MC1˜MC4) may have substantially the same layout.

Each of the first to fourth memory cells (MC1˜MC4) may include a first gate electrode layer 110, a second gate electrode layer 210, and a third gate electrode layer 310. In FIG. 5, the cross-sections of the first to third gate electrode layers (110, 210, 310) are illustrated as being circular, but are not limited thereto.

The first gate electrode layer 110 may be included in the first gate terminal (G1) of the first transistor (TR1). The first gate electrode layer 110 may be located, for example, at a point where the write word line (WWL) and the write bit line (WBL) cross each other.

The second gate electrode layer 210 may be included in the second gate terminal (G2) of the second transistor (TR2). The second gate electrode layer 210 may be located, for example, at a point where the write word line (WWL) and the write bit line (WBL) cross each other, and may overlap the first gate electrode layer 110 when viewed in the third direction (Z). The second gate electrode layer 210 may be arranged spaced apart from the first gate electrode layer 110 in the third direction (Z).

The third gate electrode layer 310 may be included in the third gate terminal (G3) of the third transistor (TR3). The third gate electrode layer 310 may be arranged spaced apart from the second gate electrode layer 210 in the second direction (Y). The third gate electrode layer 310 may be disposed between adjacent second gate electrode layers 210.

Each of the first and second read word lines (RWL1, RWL2) of FIG. 5 may be an embodiment of implementing the read word line (RWL) of FIG. 1. Each of the first and second read bit lines (RBL1, RBL2) of FIG. 5 may be an embodiment of implementing the read bit line (RBL) of FIG. 1. Each of the first and second write word lines (WWL1, WWL2) of FIG. 5 may be an embodiment of implementing the write word line (WWL) of FIG. 1. Each of the first and second write bit lines (WBL1, WBL2) of FIG. 5 may be an embodiment of implementing the write bit line (WBL) of FIG. 1.

Each of the first and second write word lines (WWL1, WWL2) may extend in the first direction (X). A plurality of write word lines including the first and second write word lines (WWL1, WWL2) may be repeatedly arranged. For example, the plurality of write word lines including the first and second write word lines (WWL1, WWL2) may be repeatedly arranged spaced apart from each other by a predetermined distance (e.g., a first interval) in the second direction (Y).

Each of the first and second read word lines (RWL1, RWL2) may extend in the first direction (X). A plurality of read word lines including the first and second read word lines (RWL1, RWL2) may be repeatedly arranged. For example, the plurality of read word lines including the first and second read word lines (RWL1, RWL2) may be repeatedly arranged spaced apart from each other by a predetermined distance (e.g., a first interval) in the second direction (Y). The first read word line (RWL1) may overlap the first write word line (WWL1) in the third direction (Z), and may be arranged below the first write word line (WWL1). The second read word line (RWL2) may overlap the second write word line (WWL2) in the third direction (Z), and may be arranged below the second write word line (WWL2).

Each of the first and second write bit lines (WBL1, WBL2) may extend in the second direction (Y). A plurality of write bit lines including the first and second write bit lines (WBL1, WBL2) may be repeatedly arranged. For example, the plurality of write bit lines including the first and second write bit lines (WBL1, WBL2) may be repeatedly arranged spaced apart from each other by a predetermined distance (e.g., a second interval) in the first direction (X).

Each of the first and second read bit lines (RBL1, RBL2) may extend in the second direction (Y). A plurality of read bit lines including the first and second read bit lines (RBL1, RBL2) may be repeatedly arranged. For example, the plurality of read bit lines including the first and second read bit lines (RBL1, RBL2) may be repeatedly arranged spaced apart from each other by a predetermined distance (e.g., the second interval) in the first direction (X). The first read bit line (RBL1) may overlap the first write bit line (WBL1) in the third direction (Z), and may be arranged below the first write bit line (WBL1). The second read bit line (RBL2) may overlap the second write bit line (WBL2) in the third direction (Z), and may be arranged below the second write bit line (WBL2).

As the widths of the read word lines (RWL1, RWL2), the write bit lines (WBL1, WBL2), the read bit lines (RBL1, RBL2), and the write word lines (WWL1, WWL2) decrease, the degree of integration of the memory cells (MC) in the memory cell array (MCA) can be improved.

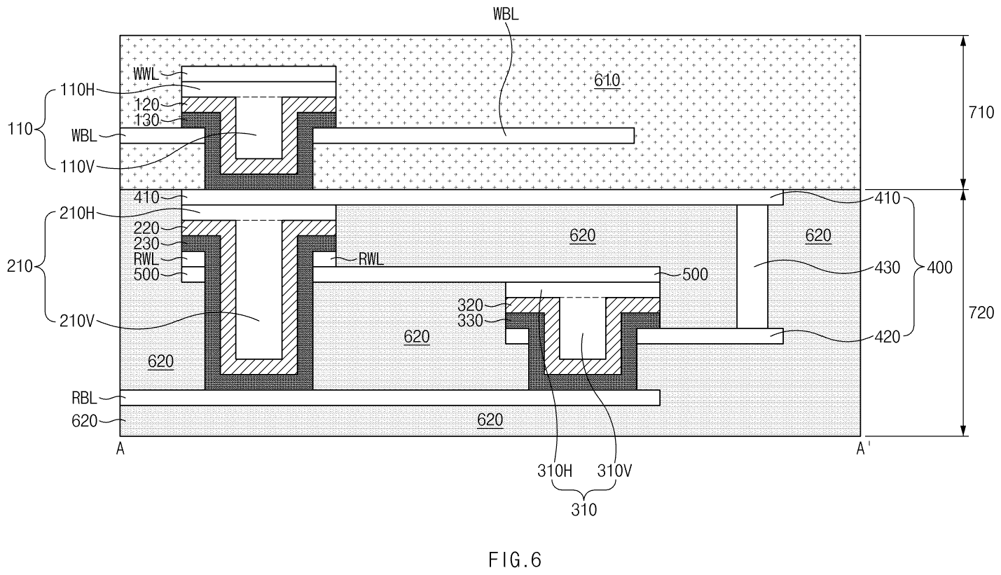

In FIG. 5, constituent components other than the write word lines (WWL1, WWL2), the read word lines (RWL1, RWL2), the write bit lines (WBL1, WBL2), the read bit lines (RBL1, RBL2), and the gate electrode layers (110, 210, 310) will herein be omitted for convenience of illustration. More detailed configurations of FIG. 5 will be described with reference to the cross-sectional view of FIG. 6 below.

FIG. 6 is a cross-sectional view illustrating the memory cell array (MCA) taken along the line A-A′ of FIG. 5 based on some embodiments of the present disclosure.

Referring to FIGS. 1, 5, and 6, the cross-section taken along the line A-A′ of FIG. 6 may include a transistor region 710 and a latch region 720.

The transistor region 710 may include a write word line (WWL), a first gate electrode layer 110, a first gate insulation layer 120, a first channel layer 130, a write bit line (WBL), and a first interlayer insulation layer 610.

The write word line (WWL) may be disposed over the first gate electrode layer 110. The write word line (WWL) may transmit a first word line signal to the first gate electrode layer 110. The write word line (WWL) may include a conductive material (e.g., at least one of polysilicon, impurity-containing polysilicon, platinum, gold, molybdenum, nickel, tungsten, titanium, aluminum copper, titanium silicide, tungsten silicide, and tantalum silicide).

The first gate electrode layer 110 may be a gate electrode layer of a first transistor (TR1) included in the first gate terminal (G1). The first gate electrode layer 110 may contact the write word line (WWL). The first gate electrode layer 110 may be disposed below the write word line (WWL). The first gate electrode layer 110 may include a conductive material (e.g., at least one of polysilicon, impurity-containing polysilicon, platinum, gold, molybdenum, nickel, tungsten, titanium, aluminum copper, titanium silicide, tungsten silicide, and tantalum silicide). The first gate electrode layer 110 may include a first vertical gate electrode layer (110V) extending in a vertical direction and a first horizontal gate electrode layer (110H) extending in a horizontal direction. The first vertical gate electrode layer (110V) may penetrate the write bit line (WBL). The first horizontal gate electrode layer (110H) may be disposed over the first vertical gate electrode layer 110V while contacting the first vertical gate electrode layer (110V). The cross-section of the first gate electrode layer 110 may have, for example, a T-shape.

The first gate insulation layer 120 may be a gate insulation layer of the first transistor (TR1) included in the first gate terminal (G1). The first gate insulation layer 120 may be disposed below the first gate electrode layer 110. The first gate insulation layer 120 may contact the first gate electrode layer 110. The first gate insulation layer 120 may electrically insulate the first gate electrode layer 110 and the first channel layer 130.

The first gate insulation layer may include an insulation material (for example, at least one of oxide, oxynitride, and nitride). The first gate insulation layer 120 may surround a bottom surface of the first horizontal gate electrode layer (110H) and the side and bottom surfaces of the first vertical gate electrode layer (110V). The first gate insulation layer 120 may also penetrate the write bit line (WBL).

The first channel layer 130 may be a region where the first channel described above in the description of FIG. 1 is formed when the first transistor (TR1) is turned on. The first channel layer 130 may be disposed below the first gate insulation layer 120. The first channel layer 130 may contact the first gate insulation layer 120. The first channel layer 130 may penetrate the write bit line (WBL). The first channel layer 130 may include an oxide semiconductor (e.g., at least one of In—Sn—Ga—Zn—O, In—Ga—Zn—O, In—Al—Zn—O, Sn—Ga—Zn—O, Al—Ga—Zn—O, Sn—Al—Zn—O, In—Zn—O, Sn—Zn—O, Al—Zn—O, Zn—Mg—O, Sn—Mg—O, In—Mg—O, and In—Ga—O). The first channel layer 130 may have a specific shape surrounding the side surface and the bottom surface of the first gate insulation layer 120.

The write bit line (WBL) may extend in the second direction (Y). The write bit line (WBL) may be arranged below the write word line (WWL). The write bit line (WBL) may be connected to the first source terminal (S1 of FIG. 1). When a first word line signal is transmitted to the first gate electrode layer 110, the write bit line (WBL) may transmit the first bit line signal obtained through a channel formed in the first channel layer 130 to the second gate electrode layer 210 through the first horizontal interconnect layer 410. The write bit line (WBL) may surround the first channel layer 130 in a horizontal direction. The write bit line (WBL) may include a conductive material (e.g., at least one of polysilicon, impurity-containing polysilicon, platinum, gold, molybdenum, nickel, tungsten, titanium, aluminum copper, titanium silicide, tungsten silicide, and tantalum silicide).

The first interlayer insulation layer 610 may fill a space around the write word line (WWL), the first gate electrode layer 110, the first gate insulation layer 120, the first channel layer 130, and the write bit line (WBL). The first interlayer insulation layer 610 may provide electrical insulation between layers that are spaced apart from each other and include a conductive material. The first interlayer insulation layer 610 may include an insulation material. For example, the first interlayer insulation layer 610 may include at least one of oxide, nitride, and oxynitride.

The latch region 720 may include a first horizontal interconnect layer 410, a second horizontal interconnect layer 420, a vertical interconnect layer 430, a second gate electrode layer 210, a second gate insulation layer 220, a second channel layer 230, a read word line (RWL), a second interconnect layer 500, a third gate electrode layer 310, a third gate insulation layer 320, a third channel layer 330, a read bit line (RBL), and a second interlayer insulation layer 620.

The second gate electrode layer 210 may be a gate electrode layer of a second transistor (TR2) included in the second gate terminal (G2). The second gate electrode layer 210 may contact the first horizontal interconnect layer 410. The second gate electrode layer 210 may be disposed below the first horizontal interconnect layer 410. The second gate electrode layer 210 may be disposed below the write bit line (WBL). The second gate electrode layer 210 may include a conductive material (e.g., at least one of polysilicon, impurity-containing polysilicon, platinum, gold, molybdenum, nickel, tungsten, titanium, aluminum copper, titanium silicide, tungsten silicide, and tantalum silicide). A storage node voltage corresponding to a voltage level of a first word line signal transmitted to the first horizontal interconnect layer 410 may be applied to the second gate electrode layer 210. The second gate electrode layer 210 may include a second vertical gate electrode layer 210V extending in a vertical direction and a second horizontal gate electrode layer 210H extending in a horizontal direction. The second vertical gate electrode layer 210V may penetrate the read word line (RWL) and the second interconnect layer 500. The cross-section of the second gate electrode layer 210 may have, for example, a T-shape. As the length of the second gate electrode layer 210 extending in the third direction (Z) increases, a portion of the second gate insulation layer 220 surrounding the second vertical gate electrode layer 210V becomes longer and the cross-section thereof becomes larger, so that capacitance of the storage node (SN) may increase.

The second gate insulation layer 220 may be a gate insulation layer of a second transistor (TR2) included in the second gate terminal (G2). The second gate insulation layer 220 may electrically insulate between the second gate electrode layer 210 and the second channel layer 230. The second gate insulation layer 220 may contact the second gate electrode layer 210. The second gate insulation layer 220 may be disposed below the second gate electrode layer 210. The second gate insulation layer 220 may include an insulation material (e.g., at least one of oxide, oxynitride, and nitride). The second gate insulation layer 220 may implement an intrinsic capacitance of the second transistor (TR2). The second gate insulation layer 220 may include a form that surrounds the bottom surface of the second horizontal gate electrode layer 210H and the side surface and bottom surface of the second vertical gate electrode layer 210V. The second gate insulation layer 220 may also penetrate the read word line (RWL) and the second interconnect layer 500.

The second channel layer 230 may be a region in which the second channel described above with reference to FIG. 1 is formed when the second transistor (TR2) is turned on. The second channel layer 230 may be disposed below the second gate insulation layer 220. The second channel layer 230 may contact the second gate insulation layer 220. The second channel layer 230 may be arranged to penetrate the read word line (RWL). The second channel layer 230 may include an oxide semiconductor (e.g., at least one of In—Sn—Ga—Zn—O, In—Ga—Zn—O, In—Al—Zn—O, Sn—Ga—Zn—O, Al—Ga—Zn—O, Sn—Al—Zn—O, In—Zn—O, Sn—Zn—O, Al—Zn—O, Zn—Mg—O, Sn—Mg—O, In—Mg—O, and In—Ga—O). The second channel layer 230 may surround the side surface and the bottom surface of the second gate insulation layer 220.

When the storage node voltage applied to the second gate electrode layer 210 has a high level, the second transistor (TR2) may be turned on so that the second channel can be formed in the second channel layer 230. The second gate insulation layer 220 may be an embodiment of implementing the storage node (SN).

The read word line (RWL) may be connected to the second source region (S2 of FIG. 1). The read word line (RWL) may transmit the second word line signal to the third gate electrode layer 310 included in each of the second source terminal (S2 of FIG. 1) and the third gate terminal (G3). The read bit line (RWL) may contact the second interconnect layer 500 that is in contact with the third gate electrode layer 310. The read word line (RWL) may surround the second channel layer 230. The read word line (RWL) may include a conductive material (e.g., at least one of polysilicon, impurity-containing polysilicon, platinum, gold, molybdenum, nickel, tungsten, titanium, aluminum copper, titanium silicide, tungsten silicide, and tantalum silicide).

The third gate electrode layer 310 may be a gate electrode layer of the third transistor (TR3). The third gate electrode layer 310 may contact the second interconnect layer 500. The third gate electrode layer 310 may receive a second word line signal via the second interconnect layer 500 contacting the read word line (RWL). The third gate electrode layer 310 may include a conductive material (e.g., at least one of doped polysilicon, platinum, gold, molybdenum, nickel, tungsten, titanium, aluminum copper, titanium silicide, tungsten silicide, and tantalum silicide).

When a second word line signal having a high level is applied to the third gate electrode layer 310, the third transistor (TR3) may be turned on. The third gate electrode layer 310 may include a third vertical gate electrode layer 310V extending in a vertical direction and a third horizontal gate electrode layer 310H extending in a horizontal direction. The third horizontal gate electrode layer 310H and the third vertical gate electrode layer 310V may contact each other. The third vertical gate electrode layer 310V may penetrate the second horizontal interconnect layer 420. The cross-section of the third gate electrode layer 310 may have, for example, a T-shape.

The third gate insulation layer 320 may be a gate insulation layer of the third transistor (TR3). The third gate insulation layer 320 may contact the third gate electrode layer 310. The third gate insulation layer 320 may be disposed below the third gate electrode layer 310. The third gate insulation layer 320 may include an insulation material. The third gate insulation layer 320 may include, for example, at least one of oxide, oxynitride, and nitride.

The third channel layer 330 may be a region where the third channel described above in the description of FIG. 1 is formed when the third transistor (TR3) is turned on. The third channel layer 330 may contact the third gate insulation layer 320. The third channel layer 330 may be disposed below the third gate insulation layer 320. The third channel layer 330 may penetrate the second horizontal interconnect layer 420. The third channel layer 330 may include an oxide semiconductor (e.g., at least one of In—Sn—Ga—Zn—O, In—Ga—Zn—O, In—Al—Zn—O, Sn—Ga—Zn—O, Al—Ga—Zn—O, Sn—Al—Zn—O, In—Zn—O, Sn—Zn—O, Al—Zn—O, Zn—Mg—O, Sn—Mg—O, In—Mg—O, In—Ga—O).

The vertical height of the second gate electrode layer 210 may be higher than the vertical height of the third gate electrode layer 310.

The read bit line (RBL) may overlap the write bit line (WBL) in the third direction (Z). The read bit line (RBL) may correspond to each of the second drain terminal (D2) and the third source terminal (S3). The read bit line (RBL) may be disposed below the second channel layer 230 and the third channel layer 330. The read bit line (RBL) may contact each of the second channel layer 230 and the third channel layer 330. The read bit line (RBL) may include a conductive material (e.g., at least one of polysilicon, impurity-containing polysilicon, platinum, gold, molybdenum, nickel, tungsten, titanium, aluminum copper, titanium silicide, tungsten silicide, and tantalum silicide).

The first interconnect structure 400 may include a first horizontal interconnect layer 410, a second horizontal interconnect layer 420, and a vertical interconnect layer 430.

The first horizontal interconnect layer 410 may extend in a first direction (X) and/or a second direction (Y) under the first channel layer 130, and may contact the vertical interconnect layer 430. The first horizontal interconnect layer 410 may correspond to the first drain terminal (D1).

The second horizontal interconnect layer 420 may surround the third channel layer 330, and may extend in the first direction (X) to contact the vertical interconnect layer 430. The second horizontal interconnect layer 420 may correspond to the third drain terminal (D3).

The vertical interconnect layer 430 may be arranged spaced apart from the second interconnect layer 500, the read word line (RWL), the third gate electrode layer 310, the third gate insulation layer 320, and the third channel layer 330.

The vertical interconnect layer 430 may be disposed between the first horizontal interconnect layer 410 and the second horizontal interconnect layer 420. The vertical interconnect layer 430 may contact the first horizontal interconnect layer 410 and the second horizontal interconnect layer 420.

The second interconnect layer 500 may contact the read word line (RWL) and the third gate electrode layer 310. The second interconnect layer 500 may extend in the second direction (Y). The second interconnect layer 500 may surround the second channel layer 230. The second interconnect layer 500 may transmit a second word line signal from the read word line (RWL) to the third gate electrode layer 310.

Each of the first interconnect structure 400 and the second interconnect layer 500 may include a conductive material (e.g., at least one of doped polysilicon, platinum, gold, molybdenum, nickel, tungsten, titanium, aluminum copper, titanium silicide, tungsten silicide, and tantalum silicide).

The second interlayer insulation layer 620 may fill a space around the first horizontal interconnect layer 410, the second horizontal interconnect layer 420, the vertical interconnect layer 430, the second gate electrode layer 210, the second gate insulation layer 220, the second channel layer 230, the read word line (RWL), the second interconnect layer 500, the third gate electrode layer 310, the third gate insulation layer 320, the third channel layer 330, and the read bit line (RBL) within the latch region 720. The second interlayer insulation layer 620 may provide electrical insulation between the layers that are spaced apart from each other and include a conductive material. The second interlayer insulation layer 620 may include an insulation material. For example, the second interlayer insulation layer 620 may include at least one of oxide, nitride, and oxynitride.

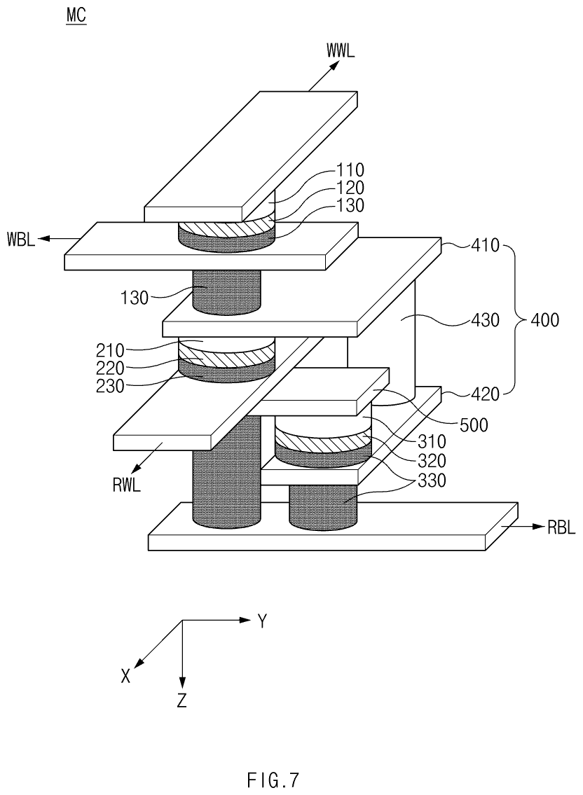

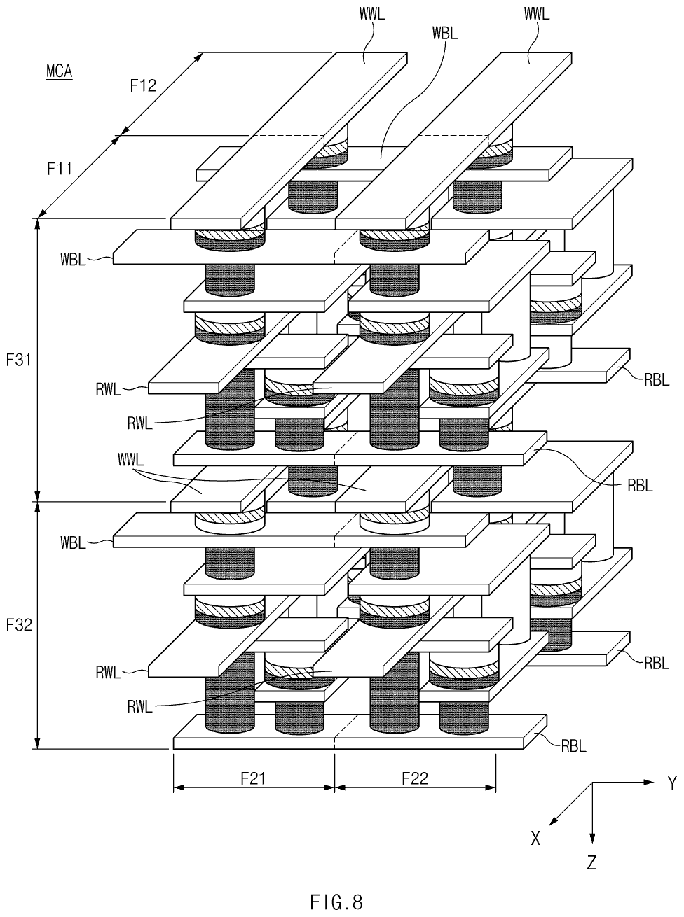

In FIGS. 7 and 8, for convenience of illustration, the first interlayer insulation layer 610 and the second interlayer insulation layer 620 illustrated in FIG. 6 are not illustrated. In FIGS. 7 and 8, descriptions overlapping with those of FIG. 6 will be omitted as much as possible.

FIG. 7 is a three-dimensional view illustrating a memory cell (MC) of FIG. 5 and the write word line (WWL), the write bit line (WBL), the read word line (RWL), and the read bit line (RBL) that penetrate the memory cell (MC) of FIG. 5 based on some embodiments of the present disclosure.

The memory cell (MC) may include a first gate electrode layer 110, a first gate insulation layer 120, a first channel layer 130, a second gate electrode layer 210, a second gate insulation layer 220, a second channel layer 230, a third gate electrode layer 310, a third gate insulation layer 320, a third channel layer 330, a first interconnect structure 400, and a second interconnect layer 500.

The write word line (WWL) may extend in the first direction (X).

The write bit line (WBL) may extend in the second direction (Y). The write bit line (WBL) may be arranged spaced apart from the write word line (WWL) in the third direction (Z).

The read word line (RWL) may extend in the first direction (X). The read word line (RWL) may be arranged spaced apart from the write bit line (WBL) in the third direction (Z).

The read bit line (RBL) may extend in the second direction (Y). The read bit line (RBL) may be arranged spaced apart from the write bit line (WBL) in the third direction (Z).

The first interconnect structure 400 may include a first horizontal interconnect layer 410, a second horizontal interconnect layer 420, and a vertical interconnect layer 430.

The first horizontal interconnect layer 410 may extend in the first direction (X) and the second direction (Y). The first horizontal interconnect layer 410 may contact each of the second gate electrode layer 210 and the vertical interconnect layer 430.

The second horizontal interconnect layer 420 may be arranged spaced apart from the first horizontal interconnect layer 410 in the third direction (Z). The second horizontal interconnect layer 420 may extend in the first direction (X).

The vertical interconnect layer 430 may be disposed between the first horizontal interconnect layer 410 and the second horizontal interconnect layer 420, and may extend in the third direction (Z).

The second interconnect layer 500 may contact the read word line (RWL), and may contact the third gate electrode layer 310. The second interconnect layer 500 may extend in the second direction (Y).

The second gate terminal (G2), which may be implemented by including the second gate electrode layer 210 and the second gate insulation layer 220, may be spaced apart from the first gate terminal (G1), which may be implemented by including the first gate electrode layer 110 and the first gate insulation layer 120, in the third direction (Z).

The third gate terminal (G3), which may be implemented by including the third gate electrode layer 310 and the third gate insulation layer 320, may be spaced apart from the second gate terminal (G2) in the second direction (Y).

FIG. 8 is a three-dimensional view illustrating a memory cell array (MCA) in which the plurality of memory cells of FIG. 5 is arranged based on some embodiments of the present disclosure.

The memory cell array (MCA) in which the three-dimensional structure of the memory cell (MC) of FIG. 7 is stacked is illustrated in FIG. 8.

In FIG. 8, for convenience of illustration, only the first to fourth write word lines (WWL1˜WWL4), the first to fourth read word lines (RWL1˜RWL4), the first to fourth write bit lines (WBL1˜WBL4), and the read bit lines (RBL1˜RBL4) are indicated by reference numbers.

Referring to FIGS. 7 and 8, the memory cell stack structure of FIG. 8 may have a stack structure in which eight memory cells (MCs) are stacked in a (2×2×2) cubic structure. Each of the eight memory cells of FIG. 8 may be substantially the same as the memory cell (MC) of FIG. 7. The planar layout structure of the memory cell array (MCA) of the cubic structure viewed from the third direction (Z) may be substantially the same as in FIG. 5.

Hereinafter, descriptions overlapping with those of FIGS. 6 and 7 will be omitted for brevity.

When classifying the above eight memory cells into first to eighth memory cells, each memory cell can be described or defined as follows.

Each of the first row (R1) and the second row (R2) may be a line extending in the second direction (Y). Each of the first column (C1) and the second column (C2) may be a line extending in the first direction (X). Each of the first floor (F1) and the second floor (F2) may be a portion extending in the first direction (X) and the second direction (Y).

The first memory cell may be arranged in the first row (R1). The first memory cell may be arranged in the first column (C1). The first memory cell may be arranged in the first floor (F1).

The second memory cell may be arranged adjacent to the first memory cell in the first direction (X). The second memory cell may be arranged in the second row (R2). The second memory cell may be arranged in the first column (C1). The second memory cell may be arranged in the first floor (F1). The second memory cell may share the first write word line (WWL1) and the first read word line (RWL1) with the first memory cell.

The third memory cell may be arranged adjacent to the first memory cell in the second direction (Y). The third memory cell may be arranged in the first row (R1). The third memory cell may be arranged in the second column (C2). The third memory cell may be arranged in a first floor (F1). The third memory cell may share the first write bit line (WBL1) and the first read bit line (RBL1) with the first memory cell.

The fourth memory cell may be arranged adjacent to the second memory cell in the second direction (Y). The fourth memory cell may be arranged adjacent to the third memory cell in the first direction (X). The fourth memory cell may be arranged in the second row (R2). The fourth memory cell may be arranged in the second column (C2). The fourth memory cell may be arranged in the first floor (F1). The fourth memory cell may share the second write bit line (WBL2) and the second read bit line (RBL2) with the second memory cell. The fourth memory cell may share the second write word line (WWL2) and the second read word line (RWL2) with the third memory cell.

The fifth memory cell may be arranged adjacent to the first memory cell in the third direction (Z). The fifth memory cell may be arranged in the first row (R1). The fifth memory cell may be arranged in the first column (C1). The fifth memory cell may be arranged in a second floor (F2).

The sixth memory cell may be arranged adjacent to the second memory cell in the third direction (Z). The sixth memory cell may be arranged in the second row (R2). The sixth memory cell may be arranged in the first column (C1). The sixth memory cell may be arranged in the second floor (F2). The sixth memory cell may share the third write word line (WWL3) and the third read word line (RWL3) with the fifth memory cell.

The seventh memory cell may be arranged adjacent to the third memory cell in the third direction (Z). The seventh memory cell may be arranged in the first row (R1). The seventh memory cell may be arranged in the second column (C2). The seventh memory cell may be arranged in the second floor (F2). The seventh memory cell may share the third write bit line (WBL3) and the third read bit line (RBL3) with the fifth memory cell.

The eighth memory cell may be arranged adjacent to the sixth memory cell in the second direction (Y). The eighth memory cell may be arranged adjacent to the seventh memory cell in the first direction (X). The eighth memory cell may be arranged adjacent to the fourth memory cell in the third direction (Z). The eighth memory cell may be arranged in the second row (R2). The eighth memory cell may be arranged in the second column (C2). The eighth memory cell may be arranged in the second floor (F2). The eighth memory cell may share the fourth write bit line (WBL4) and the fourth read bit line (RBL4) with the sixth memory cell. The eighth memory cell may share the fourth write word line (WWL4) and the fourth read word line (RWL4) with the seventh memory cell.

The first write word line (WWL1) may extend in the first direction (X). The first write word line (WWL1) may provide a first write word line signal to the first memory cell and the second memory cell. The first read word line (RWL1) may extend in the first direction (X). The first read word line (RWL1) may provide a first read word line signal to the first memory cell and the second memory cell. The first write bit line (WBL1) may extend in the second direction (Y). The first write bit line (WBL1) may provide a first write bit line signal to the first memory cell and the third memory cell. The first read bit line (RBL1) may extend in the second direction (Y). The first read bit line (RBL1) may provide a first read bit line signal to the first memory cell and the third memory cell.

The second write word line (WWL2) may extend in the first direction (X). The second write word line (WWL2) may provide a second write word line signal to the third memory cell and the fourth memory cell. The second read word line (RWL2) may extend in the first direction (X). The second read word line (RWL2) may provide a second read word line signal to the third memory cell and the fourth memory cell. The second write bit line (WBL2) may extend in the second direction (Y). The second write bit line (WBL2) may provide a second write bit line signal to the second memory cell and the fourth memory cell. The second read bit line (RBL2) may extend in the second direction (Y). The second read bit line (RBL2) may provide a second read bit line signal to the second memory cell and the fourth memory cell.

Each of the first write word line (WWL1), the first read word line (RWL1), the first write bit line (WBL1), the first read bit line (RBL1), the second write word line (WWL2), the second read word line (RWL2), the second write bit line (WBL2), and the second read bit line (RBL2) may be arranged in the first floor (F1).

The third write word line (WWL3) may extend in the first direction (X). The third write word line (WWL3) may provide a third write word line signal to the fifth memory cell and the sixth memory cell. The third read word line (RWL3) may extend in the first direction (X). The third read word line (RWL3) may provide a third read word line signal to the fifth memory cell and the sixth memory cell. The third write bit line (WBL3) may extend in the second direction (Y). The third write bit line (WBL3) may provide a third write bit line signal to the fifth memory cell and the seventh memory cell. The third read bit line (RBL3) may extend in the second direction (Y). The third read bit line (RBL3) may provide a third read bit line signal to the fifth memory cell and the seventh memory cell.

The fourth write word line (WWL4) may extend in the first direction (X). The fourth write word line (WWL4) may provide a fourth write word line signal to the seventh memory cell and the eighth memory cell. The fourth read word line (RWL4) may extend in the first direction (X). The fourth read word line (RWL4) may provide a fourth read word line signal to the seventh memory cell and the eighth memory cell. The fourth write bit line (WBL4) may extend in the second direction (Y). The fourth write bit line (WBL4) may provide a fourth write bit line signal to the sixth memory cell and the eighth memory cell. The fourth read bit line (RBL2) may extend in the second direction (Y). The fourth read bit line (RBL2) may provide a fourth read bit line signal to the sixth memory cell and the eighth memory cell.

Each of the third write word line (WWL3), the third read word line (RWL3), the third write bit line (WBL3), the third read bit line (RBL3), the second write word line (WWL4), the fourth read word line (RWL4), the fourth write bit line (WBL4), and the fourth read bit line (RBL4) may be arranged in the second floor (F2).

Each of the first to fourth write word lines (WWL1˜WWL4) may have substantially the same structure and material as the write word line (WWL) shown in FIGS. 6 and 7.

Each of the first to fourth read word lines (RWL1˜RWL4) may have substantially the same structure and material as the read word line (RWL) shown in FIGS. 6 and 7.

Each of the first to fourth write bit lines (WBL1˜WBL4) may have substantially the same structure and material as the read bit line (WBL) shown in FIGS. 6 and 7.

Each of the first to fourth read bit lines (RBL1 to RBL4) may have substantially the same structure and material as the read bit lines (RBL) shown in FIGS. 6 and 7.

The interconnect layers configured such that the first interconnect structure 400 and the second interconnect layer 500 respectively correspond to the first to eighth memory cells may not be shared with each other, and may be spaced apart from each other.

As is apparent from the above description, the semiconductor device based on some embodiments of the present disclosure may replace a capacitor designed to store data in a unit memory cell with a transistor.

The semiconductor device based on some embodiments of the present disclosure may be designed to have a structure in which a plurality of transistors included in the unit memory cell can be stacked.

The embodiments of the present disclosure may provide a variety of advantageous effects capable of being directly or indirectly recognized.

Those skilled in the art will appreciate that the embodiments of the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in the present disclosure. Furthermore, the embodiments maybe combined to form additional embodiments.

What is claimed is:

1. A memory cell comprising:
a first gate disposed to contact a write word line;
a second gate disposed below the first gate and disposed over a read bit line, the second gate penetrating a read word line;
a third gate spaced apart from the second gate and disposed over the read bit line;
a first interconnect structure disposed to partially contact the second gate, and the first interconnect structure being penetrated by the third gate; and
a second interconnect structure disposed to contact the read word line and the third gate.

2. The memory cell according to claim 1, wherein:
the first gate is disposed to penetrate a write bit line;
the write word line and the read word line are disposed to extend in a first direction; and
the write bit line and the read bit line are disposed to extend in a second direction different from the first direction.

3. The memory cell according to claim 1, wherein the first interconnect structure includes:
a first horizontal interconnect layer disposed to contact the second gate;
a second horizontal interconnect layer disposed to be penetrated by the third gate; and
a vertical interconnect layer disposed to contact the first horizontal interconnect layer and the second horizontal interconnect layer.

4. The memory cell according to claim 3, wherein:
a first channel layer is disposed to contact a side surface and a bottom surface of the first gate and disposed to contact the write bit line;
a second channel layer is disposed to contact a side surface and a bottom surface of the second gate and disposed to contact the read word line; and
a third channel layer is disposed to contact a side surface and a bottom surface of the third gate and disposed to contact the second horizontal interconnect layer.

5. The memory cell according to claim 4, wherein
each of the first to third channel layers includes an oxide semiconductor.

6. The memory cell according to claim 5, wherein
the oxide semiconductor includes at least one of In—Sn—Ga—Zn—O, In—Ga—Zn—O, In—Al—Zn—O, Sn—Ga—Zn—O, Al—Ga—Zn—O, Sn—Al—Zn—O, In—Zn—O, Sn—Zn—O, Al—Zn—O, Zn—Mg—O, Sn—Mg—O, In—Mg—O, and In—Ga—O.

7. The memory cell according to claim 2, wherein:
each of the first to third gates is disposed to extend in a third direction perpendicular to the first direction; and
the second gate is disposed spaced apart from the first gate in the third direction, and a height of the second gate in the third direction is higher than a height of the third gate in the third direction.

8. A semiconductor device comprising:
a first transistor including a first gate connected to a write word line and one terminal connected to a storage node;
a second transistor including a second gate connected to the storage node and one terminal connected to a read word line; and
a third transistor including a third gate connected to the read word line and one terminal connected to a read bit line.

9. The semiconductor device according to claim 8, wherein:
the second transistor includes another terminal connected to the read bit line; and
the third transistor includes another terminal connected to the storage node.

10. The semiconductor device according to claim 8, wherein
the first transistor includes another terminal connected to a write bit line.

11. The semiconductor device according to claim 10, wherein:
when a first word line signal applied to the write word line has a high level, the first transistor is turned on; and
when the first word line signal has a low level, the first transistor is turned off.

12. The semiconductor device according to claim 11, wherein:
when the first word line signal has a high level and a first bit line signal applied to the write bit line has a high level, data corresponding to “1” is stored in the storage node; and
when the first word line signal has a high level and the first bit line signal has a low level, data corresponding to “0” is stored in the storage node.

13. The semiconductor device according to claim 12, wherein:
when the data corresponding to “1” is stored in the storage node, the second transistor is turned on; and
when the data corresponding to “0” is stored in the storage node, the second transistor is turned off.

14. The semiconductor device according to claim 13, wherein:
when a second word line signal applied to the read word line has a high level and the second transistor is turned on, a second bit line signal having a high level is applied to the read bit line; and
when the second word line signal applied to the read word line has a low level and the second transistor is turned off, the second bit line signal having a low level is applied to the read bit line.

15. The semiconductor device according to claim 13, wherein:
the read word line is configured to receive a second word line signal having a high level to turn on the third transistor; and
the third transistor is configured to refresh data stored in the storage node.

16. A method for operating a semiconductor device, the method comprising:
applying a first word line signal to a gate of a first transistor;
storing data corresponding to a level of a first bit line signal applied to one terminal of the first transistor in a storage node connected to a second transistor;
applying a second word line signal to one terminal of the second transistor;
outputting a second bit line signal corresponding to the data to another terminal of the second transistor;
applying the second bit line signal to one terminal of a third transistor; and
refreshing the data stored in the storage node.

17. The method according to claim 16, wherein:
when the first word line signal has a high level, the first transistor is turned on; and
when the first word line signal has a low level, the first transistor is turned off.

18. The method according to claim 16, wherein:
when the first bit line signal has a high level, the data is “1”; and
when the first bit line signal has a low level, the data is “0”.

19. The method according to claim 18, wherein:
when the data is “1”, the second transistor is turned on; and
when the data is “0”, the second transistor is turned off.

20. The method according to claim 18, wherein:
when the data is “1”, the second bit line signal has a high level; and
when the data is “0”, the second bit line signal has a low level.

21. The method according to claim 20, wherein:
when the second bit line signal is at the high level, the data stored in the storage node is refreshed to “1”; and
when the second bit line signal is at the low level, the data stored in the storage node is refreshed to “0”.
